(19) United States
(12) Patent Application Publication
(10) Pub. No.: US 2021/0229525 A1
(43) Pub. Date: Jul. 29, 2021

(54) CONDUIT COMPONENT FOR A MOTOR VEHICLE HAVING DEMAND-COMPATIBLY DIMENSIONED INTEGRATED ELECTRICAL LEADS

(71) Applicant: Röchling Automotive SE & Co. KG, Mannheim (DE)

(72) Inventor: Marco Barbolini, Bolzano (IT)

(73) Assignee: Röchling Automotive SE & Co. KG

(21) Appl. No.: 17/157,024

(22) Filed: Jan. 25, 2021

(30) Foreign Application Priority Data
Jan. 27, 2020 (DE) 10 2020 101 906.8

(51) Int. Cl. B60H 1/22; B60H 1/00

(52) U.S. Cl. CPC B60H 1/2225; B60H 2001/00092; B60H 1/00021

(57) ABSTRACT

A motor-vehicle conduit component encompassing an inherently rigid conduit structure having a conduit wall that surrounds a fluid-carrying volume embodied for the passage of a fluid along a virtual conduit path; the virtual conduit path notionally penetrating centrally through the fluid-carrying volume; a plurality of electrical conductors being arranged on and/or in the conduit wall, each electrical conductor of which is electrically conductively contactable from outside the conduit component at least at a first contact location and at a second contact location arranged with a spacing along the conduit path from the first contact location; the conduit structure being inherently rigid, and the plurality of electrical conductors having a first conductor group constituting a power conductor group and having a lower length-related resistance, and a second conductor group constituting a signal conductor group and having a higher length-related resistance.

This Application claims priority in German Patent Application DE 10 2020 101 906.8 filed on Jan. 27, 2020, which is incorporated by reference herein.

### BACKGROUND OF THE INVENTION

The present invention relates to a motor-vehicle conduit component encompassing a conduit structure having a conduit wall that surrounds a fluid-carrying volume embodied for the passage of a fluid along a virtual conduit path; the virtual conduit path notionally penetrating centrally through the fluid-carrying volume; a plurality of electrical conductors being arranged on and/or in the conduit wall, each electrical conductor of which is electrically conductively contactable from outside the conduit component at least at a first contact location and at a second contact location arranged with a spacing along the conduit path from the first contact location.

A conduit component of this kind, which encompasses a flexible composite component that must be dimensionally stabilized by an additional supporting structure, is known from WO 2016/079226 A1 as a climate-control conduit component for an aircraft. This document discloses using the electrical conductors connected to the surface of the conduit component for the transfer of electrical currents of differing intensity in order to transfer operating power, controlling functional currents, and also communication signals.

DE 10 2006 001 791 A1 discloses injecting conductor traces, constituting protective resistors, into ventilation and climate-control conduits, or printing them onto their surface.

It is known from EP 1 245 361 to integrate injection-molded shaped parts having an electrical conduction function, as well as electrical components, into an injection-molded housing component using the multi-component injection molding process.

The aforementioned embodiment of WO 2016/079226 A1 is disadvantageous in that a conductor through which current is flowing heats up in accordance with Joule's first law, the heating depending on the one hand on the square of the current intensity and on the other hand linearly on the ohmic resistance of the conductor. Thus either all the electrical conductors on the conduit component must be dimensioned in accordance with the quantitatively largest expected current intensity, or the current-flow duration must be limited in accordance with the ohmic resistance of the conductors and the intensity of the current being carried. The former results in unnecessary consumption of resources, since even conductors that are predominantly lightly loaded must be designed in terms of the expected maximum load. The latter is technically impossible in practice, since a device operated via a conductor in a conduit component cannot readily be switched off without consideration of its operation.

### SUMMARY OF THE INVENTION

An object of the present invention is therefore to furnish a conduit component, recited above, for motor vehicles which makes possible, with minimal weight and with the most precise possible resource outlay, to carry electrical currents of differing intensities over a predetermined distance.

The present invention achieves the aforementioned object by way of a motor-vehicle conduit component, recited above, in which the conduit structure is inherently rigid, and in which the plurality of electrical conductors has a first conductor group constituting a power conductor group and having a lower length-related resistance, and a second conductor group constituting a signal conductor group and having a higher length-related resistance.

A “conductor group” for purposes of the present Application encompasses at least one electrical conductor. A “conductor group” will be described hereinafter as one encompassing a plurality of conductors, which should relate to the plurality of application instances.

Thanks to the inherent rigidity, the supporting structure known in the existing art for dimensional stabilization can be omitted. This reduces the weight of the conduit component for a fluid-carrying capability and fluid-carrying length that are otherwise the same, and furthermore reduces the outlay required for manufacturing it. A conduit structure encompasses in any case the conduit wall, and can moreover encompass further configurations, for instance flanges, fastening configurations such as tabs and/or eyes, and the like.

Grouping the plurality of different electrical conductors furthermore makes possible demand-compatible dimensioning thereof. A quantitatively higher electrical power level, which, for instance, transfers the power needed for operation of a connected electrical device, can thus be transferred via the power conductor group without excessive heating of the power conductor group even in a context of continuous operation. For that purpose, the electrical conductors of the power conductor group are each embodied with a lower length-related resistance than the electrical conductors of the signal conductor group.

The signal conductor group can serve to transfer control and communication signals in the context of which, as a rule, electrical power, or a high level of electrical power, is not transferred. The electrical conductors of the signal conductor group can therefore be constituted using a minimum of material.

The lower length-related resistance of the electrical conductors of the power conductor group is preferably realized by way of a larger conduction cross section, which makes possible the use of a uniformly identical electrically conductive material for both conductor groups. It is also not to be precluded, however, that the conductors of the two conductor groups have the same conduction cross section, the conductors of the first conductor group then being constituted from a material having a lower specific resistance. Such a material is usually more expensive, on a weight-related basis, than material having a lower specific resistance, so that an economization of resources is also achieved by way of the material selection. In a context of particularly large quantitative differences in transferred electrical power level, the conductors of the power conductor group, in addition to a larger conduction cross section, can be constituted from a material having a lower specific resistance as compared with those of the signal conductor group.

According to a first alternative embodiment, the plurality of electrical conductors can encompass solid-metal conductor traces. Because solid-metal conductor traces have a lower length-related resistance compared with other conductor traces of the same length and volume, in the relevant operating temperature range from −20° C. to approximately 75° C., at least the conductors of the power conductor group preferably encompass or are constituted from solid-metal traces. The signal conductor group as well can, however, encompass or be constituted from solid-metal traces.

The solid-metal conductor traces can be adhesively bonded directly onto the conduit wall, for instance if they are stable enough for that. More-delicate solid-metal conductor traces, which are more easily damaged and therefore difficult to handle, can be adhesively bonded indirectly via a carrier film carrying the conductor traces. The carrier film and its handling are robust compared with the conductor traces themselves. Additionally or alternatively, the conduit wall can be injection-applied onto the solid-metal conductor traces, and/or the solid-metal conductor traces, with the exception of the first and the second contact location, can be embedded into material of the conduit wall. This applies especially to conductor traces having sufficient physical stability to withstand injection application in an injection-molding cavity. This applies especially, but not only, to conductor traces of the power conductor group, if they have a relatively large conduction cross section.

Additionally or alternatively, the plurality of electrical conductors can encompass a conductor trace printed onto a surface of the conduit wall, and/or can encompass at least one electrical conductor generated by injection molding, or extruded, from plastic filled with electrically conductive material. Conductor traces that are printed on, injected on or injection-applied, or extruded as a rule also contain metal, but in contrast to the aforementioned solid-metal conductor traces it is embedded in particle form into a matrix, in particular a polymer matrix. The specific resistance of an electrically conductive material that can be printed on, processed by injection molding, or extruded is therefore, as a rule, higher than that of solid metal, regardless of the purity of the metal.

The inherently rigid conduit structure is preferably generated by injection molding and/or blow molding, so that dimensionally consistent components can be furnished inexpensively in large quantities.

In order to ensure a simple capability for checking their integrity, the plurality of electrical conductors can be arranged at least in part on the outer side, facing away from the fluid-carrying volume, of the conduit structure.

On the other hand, for shielding from external influences, in particular mechanical and/or chemical influences, the plurality of electrical leads can be arranged at least in part on the inner side, facing toward the fluid-carrying volume, of the conduit structure.

It is furthermore possible to achieve a capability for checking, as well as substantially identical electrical resistance values for conductors of a conductor group, by the fact that at least some of the electrical conductors of the power conductor group extend parallel to one another, and at least some of the electrical conductors of the signal conductor group extend parallel to one another.

The present invention furthermore relates to a motor vehicle having a conduit component embodied as described above, in particular constituting a component of a climate-control conduit for the passage of climate-controlled air. The present invention furthermore relates to a use of a conduit component configured as described above, in a vehicle, for conveying a fluid, in particular a gas.

These and other objects, aspects, features and advantages of the invention will become apparent to those skilled in the art upon a reading of the Detailed Description of the invention set forth below taken together with the drawings which will be described in the next section.

### BRIEF DESCRIPTION OF THE DRAWINGS

The invention may take physical form in certain parts and arrangement of parts, a preferred embodiment of which will be described in detail and illustrated in the accompanying drawings which forms a part hereof and wherein:

FIG. 1 is a schematic side view of an embodiment according to the present invention of a motor-vehicle conduit; and

FIG. 2 is a schematic cross-sectional view through the conduit component of FIG. 1 along a section plane II-II in FIG. 1 which is orthogonal to the conduit path.

### DESCRIPTION OF PREFERRED EMBODIMENTS

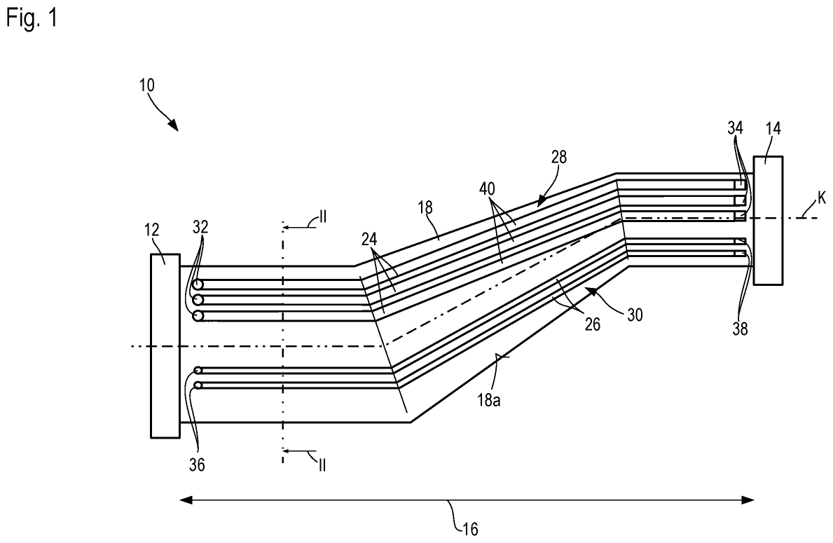

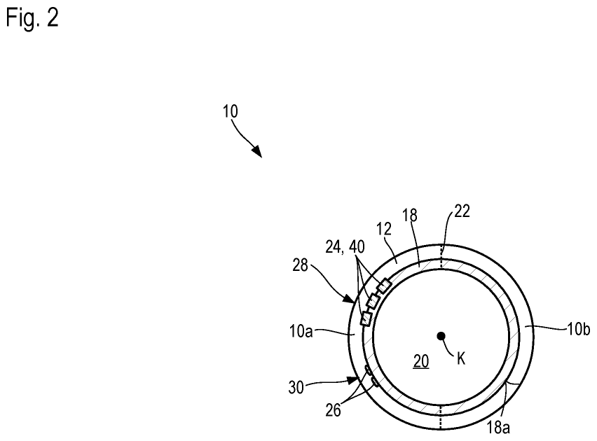

Referring now to the drawings wherein the showings are for the purpose of illustrating preferred and alternative embodiments of the invention only and not for the purpose of limiting the same, in FIGS. 1 and 2, an embodiment according to the present invention of a motor-vehicle conduit component of the present invention is labeled in general with the number 10. Conduit component 10 has at the ends a respective attachment flange 12, 14, which flanges are arranged with a spacing 16 from one another along a virtual conduit path K. Extending between attachment flanges 12 and 14, along virtual conduit path K, is a conduit wall 18 having a substantially circular cross section. The cross section can also have a shape other than a circular one. The circular shape is recited merely as an example.

Also by way of example, conduit component 10 is constituted from two injection-molded conduit component shells 10a and 10b that are heat-sealed to one another. Conduit component 10 can, however, also be blow-molded or manufactured using a combination of blow-molding and injection-molding processes. For example, conduit wall 18 surrounding a fluid-carrying volume 20 can be blow-molded, the end-located attachment flanges 12 and 14 then having been injection-applied onto conduit wall 18.

In the injection-molded conduit component 10 depicted by way of example in FIGS. 1 and 2, in FIG. 2 the joining plane extending orthogonally to the drawing plane of FIG. 2 and parallel to the drawing plane of FIG. 1 is depicted with dashed lines and labeled with a reference character 22. Conduit component 10 is inherently rigid, and requires no additional supporting structure to maintain its shape once it has been achieved. The material from which the conduit component is constituted is a thermoplastic polymer, preferably a polyolefin.

Arranged on outer side 18a, facing away from fluid-carrying volume 20, of conduit wall 18 is a plurality of electrical conductors 24 and 26. Electrical conductors 24, of which, by way of example, three electrical conductors 24 extending parallel to one another are depicted, constitute a power conductor group 28 having a lower length-related electrical resistance. Electrical conductors 26, of which, by way of example, two electrical conductors 26 extending parallel to one another are depicted, constitute a signal conductor group 30 having a higher length-related electrical resistance.

Electrical conductors 24, which extend from a first contact location 32 to a second contact location 34 located remotely along virtual conduit path K, serve to transfer electrical power that is necessary for operation of an electrical apparatus, for example an electric fan or another electrical load.

Electrical conductors 26, which also extend from a first contact location 36 to a second contact location 38, serve to transfer electrical communication signals, which are represented substantially by a potential difference or a change in electrical potentials between a reference potential and an electrical potential of electrical conductor 26 and thus do not require the transfer of appreciable electrical power, and can therefore be furnished inexpensively with a higher length-related electrical resistance.

First contact locations 32 and 36 and second contact locations 34 and 38 are respectively embodied, by way of example, as solder attachment points onto which an electrical lead that extends further can be soldered. Alternatively or additionally, the aforesaid contact locations can be embodied, individually or in their entirety, as a plug connection configuration, for example as contact pins projecting from outer side 18a of conduit wall 18 or as contact sockets reachable from outer side 18a of conduit wall 18.

In the present case, electrical conductors 24 are embodied as solid metal leads 40 onto which conduit component shell 10a has been injection-applied. For that purpose, before the injection-molding operation, metal leads 40 were laid into recesses provided therefor in the injection-molding cavity for manufacturing conduit component shell 10a. As a result of this injection-application, metal leads 40 are recessed at least over part of their thickness extent into conduit wall 18. Divergently from what is depicted in FIG. 2, a metal lead 40 can also be recessed completely into conduit wall 18 if the thickness of conduit wall 18 is sufficient.

In contrast to electrical conductors 24 of power conductor group 28, electrical conductors 26 of signal conductor group 30 are extruded onto or printed onto outer side 18a of conduit wall 18. Electrical conductors 26 are therefore constituted from a polymer filled with electrically conductive particles, a polymer compatible with the polymer of conduit wall 18 being selected as the matrix polymer carrying the particles in order to ensure a connection of electrical conductors 26 to conduit wall 18 which is as durable, and as simple to produce, as possible.

The advantage of printing or extruding electrical conductors onto outer wall 18a of conduit wall 18 is the almost unrestrictedly selectable shape, and likewise almost unrestrictedly selectable routing, of electrical conductors 26. Electrical conductors 24 are also adjustable in terms of their routing, but because they are configured from solid metal, and furthermore because of their larger conductive cross section compared with that of electrical conductors 26, the selection of their routing is subject to more restrictive boundary conditions than is the case for electrical conductors 26.

As indicated schematically in FIG. 1, the routing direction and/or flow cross section of conduit component 10 along virtual conduit path K can change. Divergently from the multiply angled routing that is depicted, conduit 10 can additionally or alternatively extend along a curved conduit path.

By way of conduit component 10 presented here, electrical currents for operating electrical loads, as well as electrical communication signals, can be transferred via conduit component 10, the resource consumption for producing electrical conductors being minimized as a result of the demand-compatible dimensioning of the electrical conductors used for that purpose.

While considerable emphasis has been placed on the preferred embodiments of the invention illustrated and described herein, it will be appreciated that other embodiments, and equivalences thereof, can be made and that many changes can be made in the preferred embodiments without departing from the principles of the invention. Furthermore, the embodiments described above can be combined to form yet other embodiments of the invention of this application. Accordingly, it is to be distinctly understood that the foregoing descriptive matter is to be interpreted merely as illustrative of the invention and not as a limitation.

1-8. (canceled)

9. A motor-vehicle conduit component encompassing an inherently rigid conduit structure having a conduit wall that surrounds a fluid-carrying volume embodied for the passage of an associated fluid along a virtual conduit path; the virtual conduit path notionally penetrating centrally through the fluid-carrying volume; a plurality of electrical conductors being arranged on and/or in the conduit wall, each electrical conductor of which is electrically conductively contactable from outside the conduit component at least at a first contact location and at a second contact location arranged with a spacing along the conduit path from the first contact location, wherein the inherently rigid conduit structure is inherently rigid, and the plurality of electrical conductors has a first conductor group constituting a power conductor group and having a lower length-related resistance, and a second conductor group constituting a signal conductor group and having a higher length-related resistance.

10. The motor-vehicle conduit component according to claim 9, wherein the plurality of electrical conductors encompass solid-metal conductor traces.

11. The motor-vehicle conduit component according to claim 10, wherein a bond between the solid-metal conductor traces and the conduit wall is realized by at least one of the following:
the solid-metal conductor traces are adhesively bonded onto the conduit wall, and
the conduit wall is injection-applied onto the solid-metal conductor traces, and
the solid-metal conductor traces, with the exception of the first and the second contact location, are embedded into material of the conduit wall.

12. The motor-vehicle conduit component according to claim 9, wherein the plurality of electrical conductors encompasses at least one of:
a conductor trace printed onto a surface of the conduit wall, and
at least one electrical conductor generated by injection molding, or extrusion, from plastic filled with electrically conductive material.

13. The motor-vehicle conduit component according to claim 9, wherein the inherently rigid conduit structure is generated by at least one of injection molding and blow molding.

14. The motor-vehicle conduit component according to claim 9, wherein the plurality of electrical conductors are arranged at least in part on the outer side, facing away from the fluid-carrying volume, of the inherently rigid conduit structure.

15. The motor-vehicle conduit component according to claim 9, wherein the plurality of electrical leads are arranged at least in part on the inner side, facing toward the fluid-carrying volume, of the inherently rigid conduit structure.

16. The motor-vehicle conduit component according to claim 9, wherein at least some of the electrical conductors of the power conductor group extend parallel to one another, and at least some of the electrical conductors of the signal conductor group extend parallel to one another.

17. The motor-vehicle conduit component according to claim 11, wherein the solid-metal conductor traces are adhesively bonded onto the conduit wall indirectly via a carrier film carrying the solid-metal conductor traces.

18. The motor-vehicle conduit component according to claim 12, wherein at least one solid-metal conductor trace of the signal conductor group encompasses at least one of:
a conductor trace printed onto a surface of the conduit wall, and
at least one electrical conductor generated by injection molding or extrusion from plastic filled with electrically conductive material.
